(19) United States
(12) Patent Application Publication
(10) Pub. No.: US 2010/0218721 A1
(43) Pub. Date: Sep. 2, 2010

(54) Hollow-cathode discharge apparatus for plasma-based processing

(75) Inventors: Der-Jun Jan, Longtan shiang (TW); Shin-Wu Wei, Longtan Shiang (TW); Chi-Fong Ai, Longtan Shiang (TW)

Correspondence Address: Jackson Intellectual Property Group PLLC, 106 Starvale Lane, Shipman, VA, 22971, US

(73) Assignee: ATOMIC ENERGY COUNCIL - INSTITUTE OF NUCLEAR ENERGY RESEARCH, Taoyuan (TW)

(21) Appl. No.: 11/896,738

(22) Filed: Sep. 5, 2007

(51) Int. Cl. C23C 16/513; C23C 16/448; C23C 16/505

(52) U.S. Cl. 118/723 HC

(57) ABSTRACT

A hollow-cathode discharge apparatus is disclosed for plasma-based processing. The hollow-cathode discharge apparatus includes a vacuum chamber, a hollow cathode disposed in the center of the vacuum chamber, a carrier for synchronously carrying a plurality of work-pieces in the vacuum chamber and a driving element for driving the carrier.

### BACKGROUND OF INVENTION

1. Field of Invention

The present invention relates to a hollow-cathode discharge apparatus for plasma-based processing and, more particularly, to a structurally simple hollow-cathode discharge apparatus for generating high-density plasma based on the hollow cathode effect to process or coat many three-dimensional (“3D”) work-pieces to reduce the cost of mass production.

2. Related Prior Art

A hollow cathode is an efficient apparatus to generate high-density plasma because plasma particles and photons are confined in cavities defined therein so that gas ionization and light emission are increased. When the electrons of the plasma come close to the walls of the cavities with negative charges, the electrons are repelled by the walls of the cavities so that the electrons reciprocate in the hollow cathode, increasing chances that the electrons hit neutral gas and therefore the density of the plasma. Therefore, at a same power, the density of the plasma generated by a hollow cathode is 1 to 3 orders higher than the density of the plasma generated by a pair of parallel planar electrodes. A hollow cathode is suitable for plasma-based pre-processing and plasma polymerization when it is connected to a radio-frequency (“RF”) generator.

Various hollow cathodes have been devised for plasma-based processing. As disclosed in U.S. Pat. No. 6,066,826, a hollow cathode is used with magnets to generate a high-density plasma to process flexible plastic substrates. As disclosed in U.S. Pat. No. 5,007,373, a spiral hollow cathode is used to generate high-density plasma to deposit diamond foils. These hollow cathodes are two-dimensional structures for processing or coating substrates; however they are not suitable for processing or coating 3D work-pieces.

As disclosed in U.S. Pat. No. 6,528,947, a cellular hollow cathode is used to process or coat 3D work-pieces. However, this cellular hollow cathode can process or coat only one 3D object at a time and is therefore not suitable for mass production.

The present invention is therefore intended to obviate or at least alleviate the problems encountered in prior art.

### SUMMARY OF INVENTION

The primary objective of the present invention to provide a structurally simple hollow-cathode discharge apparatus for generating high-density plasma based on the hollow cathode effect to process or coat many 3D work-pieces to reduce the cost of mass production.

According to the present invention, a hollow-cathode discharge apparatus is disclosed for plasma-based processing. The hollow-cathode discharge apparatus includes a vacuum chamber, a hollow cathode disposed in the center of the vacuum chamber, a carrier for synchronously carrying a plurality of work-pieces in the vacuum chamber and a driving element for driving the carrier.

Other objectives, advantages and features of the present invention will become apparent from the following description referring to the attached drawings.

### BRIEF DESCRIPTION OF DRAWINGS

The present invention will be described via the detailed illustration of three embodiments referring to the drawings.

FIG. 1 is a side view of a hollow-cathode discharge apparatus according to the first embodiment of the present invention.

FIG. 2 is a perspective view of a hollow cathode for use in the hollow-cathode discharge apparatus shown in FIG. 1.

FIG. 3 is a perspective view of a hollow cathode for use in a hollow-cathode discharge apparatus according to the second embodiment of the present invention.

FIG. 4 is a perspective view of a hollow cathode for use in a hollow-cathode discharge apparatus according to the third embodiment of the present invention.

### DETAILED DESCRIPTION OF EMBODIMENTS

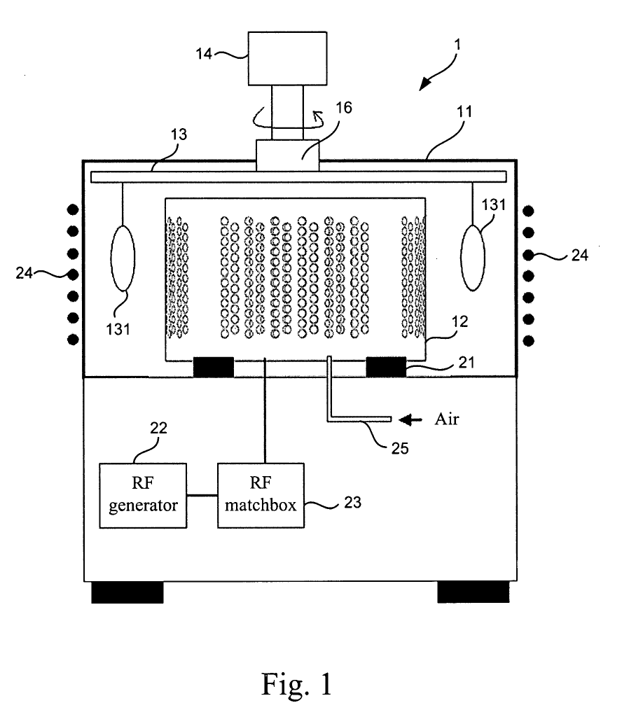

Referring to FIG. 1, a hollow-cathode discharge apparatus includes a chamber 11, a hollow cathode 12, a carrier 13 and a driving element 14 according to a first embodiment of the present invention. Based on the hollow cathode effect, the hollow-cathode discharge apparatus generates high-density plasma to process the surfaces of many 3D work-pieces or coat the 3D work-pieces with PECVD foils in a reduced period of time at a reduced cost for mass production.

Air is expelled from the chamber 11 by a pump (not shown). The chamber 11 and such a pump together form a vacuum coating system 1. The chamber 11 may be square or circular.

The hollow cathode 12 is disposed in the center of the chamber 11. The hollow cathode 12 is separated from the chamber 11 by an electrically insulating ceramic element 21. The hollow cathode 12 is connected to an RF generator 22 that operates at 1 Hz to 100 MHz.

The carrier 13 is used to carry many 3D work-pieces 131 at a time. The carrier 13 may be of a floating voltage or grounded. The carrier 13 is connected to a driving element 14 through a gear set 16. The driving element 14 may be a motor. The driving element 14 is used to drive the carrier 13 through the gear set 16 so that the carrier 13 causes the 3D work-pieces 131 to move around the hollow cathode 12 like planets moving around a star.

Preferably, the chamber 11 is circular. The hollow cathode 12 is disposed in the center of the chamber 11. The hollow cathode 12 is separated from the chamber 11 by an electrically insulating ceramic element 21. Through an RF matchbox 23, the hollow cathode 12 is connected to the RF generator 22 that operates at 1 Hz to 100 MHz. Based on electrical feed-through, the hollow electrode 12 generates plasma. To increase the density of the plasma, a direct current power supply is connected to a coil 24 provided around the chamber 11 to generate a magnetic field parallel to the axis of the chamber 11. Thus, paths are increased for the electrons of the plasma to increase the chances that the electrons hit neutral gas. The neutral gas is directly provided into the hollow cathode 12 through a pipe 25. Alternatively, the neutral gas is provided into the chamber 11 and then provided into the hollow cathode 12 through apertures defined in a lower portion of the hollow cathode 12. Thus, the ionization of the neutral gas is increased.

The 3D work-pieces 131 are hung on the carrier 13. The driving element 14 is used to drive the carrier 13 through the gear set 16 so that the carrier 13 causes the 3D work-pieces 131 to move around the hollow cathode 12 like planets moving around a star, and this movement is called “revolution.” Moreover, the gear set 16 may cause each of the 3D work-pieces 131 to spin about its own axis, and this movement is called “rotation.” Thus, all sides of each of the 3D work-pieces 131 are evenly processed by the plasma. The carrier 13 may be modified so that several 3D work-pieces 131 can be hung in a string and many strings can be hung on the carriers 13 at a time. Thus, many 3D work-pieces 131 can be processed by the plasma at a time.

Therefore, based on the hollow cathode effect, the structurally simple hollow-cathode discharge apparatus generates the high-density plasma to handle the plasma-based pre-processing of the 3D work-pieces or coat the 3D work-pieces with PEVCD foils. Moreover, the magnetic field is used to increase the density of the plasma. Thus, the time required for processing or coating the 3D work-pieces is reduced. Many 3D work-pieces are processed at a time. The process is simplified, the cost reduced, and the throughput increased.

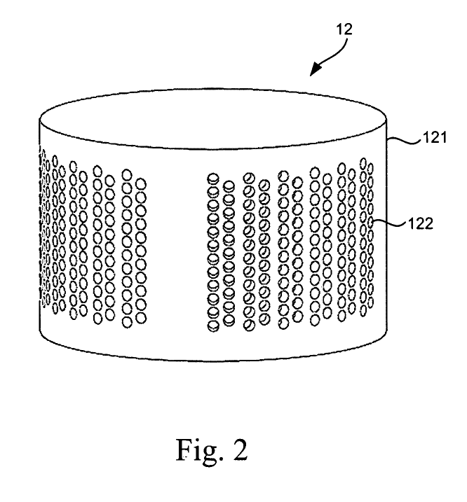

Referring to FIG. 2, the hollow cathode 12 is made of aluminum or stainless steel in a mechanical manner. The hollow cathode 12 includes a cylinder 121 and a plurality of cavities 122 evenly defined in the cylinder 121. The cavities 122 are circular or polygonal. The ratio of the diameter of the cavities 122 to the depth of the same is 1:1 to 1:5. The preferred ratio is 1:3.

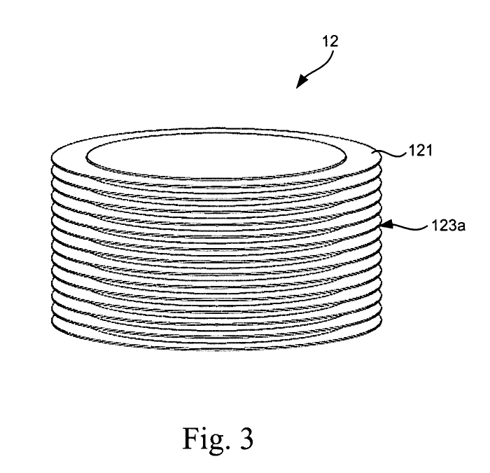

Referring to FIG. 3, there is shown a hollow cathode for use in a hollow-cathode discharge apparatus according to a second embodiment of the present invention. The second embodiment is identical to the first embodiment except including a plurality of annular grooves 123a instead of the cavities 122. The ratio of the width of the annular grooves 123a to the depth of the same is 1:1 to 1:5 and preferably 1:3.

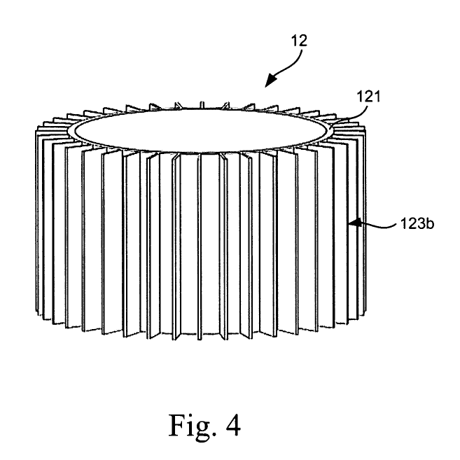

Referring to FIG. 4, there is shown a hollow cathode for use in a hollow-cathode discharge apparatus according to a third embodiment of the present invention. The third embodiment is identical to the second embodiment except including a plurality of longitudinal grooves 123b instead of the annular grooves 123a. The ratio of the width of the longitudinal grooves 123b to the depth of the same is 1:1 to 1:5 and preferably 1:3.

The hollow-cathode discharge apparatus is advantageous over prior art. The structure of the hollow cathode 12 is simple. The density of the plasma is high. It can process or coat 3D work-pieces. Used with a magnetic field, it can further increase the density of the plasma. The process is simplified, the cost reduced, and the throughput increased.

The present invention has been described via the detailed illustration of the embodiments. Those skilled in the art can derive variations from the embodiments without departing from the scope of the present invention. Therefore, the embodiments shall not limit the scope of the present invention defined in the claims.

1. A hollow-cathode discharge apparatus for plasma-based processing comprising:
a vacuum chamber;
a hollow cathode disposed in the center of the vacuum chamber;
a carrier for synchronously carrying a plurality of work-pieces in the vacuum chamber; and
a driving element for driving the carrier.

2. The hollow-cathode discharge apparatus according to claim 1, wherein the shape of the vacuum chamber is selected from a group consisting of square and circular.

3. The hollow-cathode discharge apparatus according to claim 1, wherein the shape of the hollow cathode is circular.

4. The hollow-cathode discharge apparatus according to claim 3, wherein the hollow cathode comprises a cylinder and a plurality of cavities defined in the cylinder in a mechanical manner.

5. The hollow-cathode discharge apparatus according to claim 4, wherein the shape of the cavities is selected from a group consisting of circular or polygonal.

6. The hollow-cathode discharge apparatus according to claim 4, wherein the ratio of the diameter of the cavities to the depth of the same is 1:1 to 1:5.

7. The hollow-cathode discharge apparatus according to claim 3, wherein the hollow cathode comprises a cylinder and a plurality of grooves defined in the cylinder in a mechanical manner.

8. The hollow-cathode discharge apparatus according to claim 7, wherein the grooves are annular grooves.

9. The hollow-cathode discharge apparatus according to claim 7, wherein the grooves are longitudinal grooves.

10. The hollow-cathode discharge apparatus according to claim 7, wherein the ratio of the width of the grooves to the depth of the same is 1:1 to 1:5.

11. The hollow-cathode discharge apparatus according to claim 1 comprising a gear set for connecting the carrier to the driving element so that the work-pieces revolve around the hollow cathode.

12. The hollow-cathode discharge apparatus according to claim 1 comprising a radio-frequency generator connected to the hollow cathode.

13. The hollow-cathode discharge apparatus according to claim 12, wherein the radio-frequency generator operates at 1 Hz to 100 MHz.

14. The hollow-cathode discharge apparatus according to claim 1, wherein the carrier is of a floating voltage.

15. The hollow-cathode discharge apparatus according to claim 1, wherein the carrier is grounded.
